(19) United States
(12) Patent Application Publication
(10) Pub. No.: US 2026/0223630 A1
(43) Pub. Date: Jul. 30, 2026

(54) APPARATUS AND METHOD FOR BONDING COMPONENTS AND SUBSTRATES

(71) Applicant: BESI SWITZERLAND AG, Steinhausen (CH)

(72) Inventors: Brian PULIS, Steinhausen (CH); Fabian HURSCHLER, Steinhausen (CH); Dietmar KRAUSE, Steinhausen (CH)

(21) Appl. No.: 19/144,827

(22) PCT Filed: Jan. 1, 2024
(86) PCT No.: PCT/IB2024/050006

§ 371 Date: Jun. 30, 2025

(30) Foreign Application Priority Data
Dec. 31, 2022 (DE) 10 2022 135 082.7

(51) Int. Cl. H10P 72/30; H10P 72/00

(52) U.S. Cl. CPC H10P 72/3222; H10P 72/0446; H10P 72/0611; H10P 72/3214; H10P 72/3302

(57) ABSTRACT

The invention relates to an apparatus for bonding one or more components and one or more substrates, whereby the apparatus comprises a bonding station, a transport device for transporting the substrates along a trajectory from one or more loading stations via the bonding station, to one or more unloading stations for unloading the substrates.

### FIELD

The present disclosure relates to an apparatus for bonding one or more components, such as NAND and DRAM memory dies, and one or more substrates, as well as a method of bonding one or more components and one or more substrates using such an apparatus.

### BACKGROUND

Different types of die bonder equipment are available addressing various semiconductor market segments, for example thin-die specific systems exist with highly specialized components like die ejection systems, bond head tooling and heater systems on the substrate handlers.

The substrate handlers are typically based on a clamp feeder principle where substrates or strips are moved across the substrate handler and to the process positions by a number of feeder clamps. This requires the clamps to grip the substrate on the side and to hand them over from one clamp to the next. This is a state-of-the art solution that allows for parallel processing of more than one substrate on the same substrate handler.

Generally, substrates in today's production are pushed from a substrate input magazine onto the substrate handler. A roller drive is used to move them into a substrate output magazine.

As the feeder concept allows for parallel handling of more than one substrate on the substrate handler and as no die sorting functionality is required, common die bonders are equipped with only one substrate handler and still achieve a reasonable throughput.

US 2013/0008599 A1 for instance discloses a semiconductor mounting apparatus having a dispensing station configured to dispense adhesive portions to the substrate locations of a substrate, a bonding station configured to place semiconductor chips on the substrate locations and a transport device configured to transport the substrates along a transport path.

KR 102106884 B1 for example discloses a device and method for transporting a substrate from a substrate accommodating body of a loader part to a transport lane, wherein a bonding control unit of the device dispatches the substrate to a substrate accommodating body of an unloader part as a die-mounted substrate in the event that bonding of all dies to the substrate by a bonding head has been completed, and returns the substrate to the substrate accommodating body of the loader part as a substrate for die mounting in the event that bonding of all dies to the substrate by the bonding head has not been completed.

JP 2022/013070 A furthermore discloses a manufacturing apparatus of an article comprising: a supply part of supplying a workpiece; a mounting component holding part which can hold a plurality of mounting components; a mounting component grade information storage part that stores grade information of each mounting component held by the mounting component holding part; a housing part that houses the workpiece onto which each mounting component is mounted; and a buffer part that stores the workpiece onto which each mounting component is mounted on only one part of a mounted region of the workpiece.

WO 2022/097415 A1 moreover discloses conveying a member to be supplied from a rotor to a supply position, and the member to be supplied, having been mounted with a workpiece, is conveyed out to an unloader. If a workpiece supply source no longer has workpieces of the grade to be supplied before mounting the workpiece on the member to be supplied, then that member to be supplied is conveyed from a shuttle to a standby position. Another member to be supplied is conveyed to the supply position that has been vacated.

The common clamp feeder concept on current substrate handling systems, however, is not suitable for the substrates with a stiffness below a certain value. With every clamping step, the risk of damaging the strip or the dies that were already attached in a prior step increases. Also, at each process position, the strip needs to be held down before the process and the downholding needs to be released after the process. This is typically done with an underpressure, that means a pressure below atmospheric pressure, and a mechanical downholder tool, both of which induce a physical impulse or shock to the substrate that could damage strip or the attached dies on it.

On some conventional systems, the substrate is moved to or onto a heating device more than once, which results in multiple heating and cooling cycles for the substrate.

This is especially relevant for systems that reply on a buffer storage like a magazine to store a substrate for bonding dies of a different bin code, will impose more than one heat up and heat down cycle on the substrates every time a substrate is loaded to and unloaded from the carriage.

Each time, a substrate is clamped, released, heated, cooled, or otherwise manipulated the physical properties like surface planarity can change. Above a certain level of change, the risk of damaging the substrate further increases, for instance due to collision with a mechanical part of the system or a magazine.

In addition, a complicated mechanical setup has to be done during a product conversion or a new recipe creation with the current substrate handling concepts. Small variations in the material or slight mis-adjustments during the setup often result in strips being damaged or destroyed by crashes against mechanical parts during loading, transporting, guiding, down holding and unloading.

Current die bonders with thin-die capability typically have a single substrate handler and thus do not offer a die sorting possibility from wafer to substrate based on their quality classification (bin code). The sorting by bin code has to be either done separately by a specialized upstream equipment that sorts the wafers with mixed bin codes to carriers that then contain only dies of one bin code each or alternatively by a multi-pass process on one or more conventional die bonders where in each pass only dies of one bin code are produced. Both solutions have significant drawbacks in terms of cost efficiency, demand for expensive clean-room floor space and they increase the risk of damage due to the extra handling of the material.

Moreover, as typical current systems with single strip handlers do not allow for die sorting, additional investment is needed to provide this as an upstream step on a separate system.

Additionally, conventional substrate handlers require long and risky product setups and change-overs due to the aforementioned complicated mechanical setup.

An object of the present invention is thus to provide an apparatus and/or method for bonding components and substrates, wherein relatively thin substrates (e.g. <100 μm) can be safely handled for the purpose of bonding components, such as semiconductor dies, thereto.

A further object of the invention is to provide an apparatus and/or method for bonding components and substrates, allowing the sorting of various bin codes, while at the same time achieving a relatively high throughput.

An even further object of the invention is to provide an apparatus and/or method for bonding components and substrates, wherein a reduction in cost of ownership is achieved.

A yet even further object of the invention is to provide an apparatus and/or method for bonding components and substrates, wherein a relatively higher overall uptime is achieved.

### SUMMARY OF THE INVENTION

According to the present invention, an apparatus for bonding one or more components and one or more substrates is provided, the apparatus comprising:
a bonding station for bonding the components to the substrates, wherein the components are to be bonded to the substrates at the bonding station;
a transport device for each time transporting the substrates along a trajectory from one or more loading stations, via the bonding station, to one or more unloading stations, the transport device comprising:
a carriage having a flat support surface for supporting the substrates thereon;
a carriage moving device for moving the carriage along the trajectory; and
a downholding device for holding the substrates on the support surface;
one or more loading stations for loading the substrates onto the carriage, comprising one or more pull-in devices for pulling the substrates onto the support surface of the carriage; and
one or more unloading stations for unloading the substrates after the components have been bonded thereto at the bonding station, comprising one or more pull-out devices for pulling the substrates off of the support surface of the carriage. Due to the one or more substrates being pulled-in at the loading stations and being pulled-out at the unloading stations rather than pushed-in or pushed-out, as well as the one or more substrates being moved along the whole trajectory by the carriage, very thin substrates can be handled (such as having a thickness of <100 μm), without, or at least with a reduced, risk of damaging the substrates.

As the substrates are supported by the same carriage in between loading and unloading and as each process step (e.g. cleaning, bonding, post-bond inspection) is performed on that carriage, no physical stress is induced for steps like re-clamping of the substrate or hand-over to another carrier. Also, no additional time is needed to apply and remove the downholding function at each process position and transfers of substrates are significantly reduced.

Further, systems that reply on a buffer storage like a magazine to store a substrate for bonding dies of a different bin code, will impose more than one heat up and heat down cycle on the substrates every time a substrate is loaded to and unloaded from the carriage.

The reduced cost of a single transport device enables configuration of for instance four or more transport devices per system to support multi-bin handling at high throughput and thus offering a competitive cost-per-bond.

Moreover, the above apparatus allows for the selection of a speed-optimized point to line pick-and-place over a heavy and slower gantry alternative.

An embodiment relates to an aforementioned apparatus,
wherein the loading stations comprise one or more input magazines for storing therein the substrates, wherein the pull-in devices are configured for pulling the substrates from the input magazines onto the support surface of the carriage; and/or
wherein the unloading stations comprise one or more output magazines for storing therein the substrates after the components have been bonded thereto at the bonding station, wherein the pull-out devices are configured for pulling the substrates off of the support surface of the carriage and into the output magazines.

As mentioned in the foregoing, pulling the often ultra-thin substrates out of the input magazines directly onto the carriage and from the carriage directly into the output magazines reduces the risk of damaging the substrates and thus ensures a relatively high yield. Common loading and unloading modules are based on pusher rods or roller drives which show a higher rate of strip jamming issues.

An embodiment relates to an aforementioned apparatus, wherein the pull-in devices comprises:
one or more pull-in grippers (15) for gripping a, when viewed in a movement direction (X) along the trajectory, front end (25) of the substrates (3), such as an end (26) facing the carriage (11); and
one or more pull-in gripper moving devices (16) for moving the pull-in grippers back and forth in a moving direction parallel to the trajectory; and/or
wherein the pull-out devices (10) comprise:
one or more pull-out grippers (27) for gripping a, when viewed in a movement direction along the trajectory, front end (25) of the substrates; and
one or more pull-out gripper moving devices (28) for moving the pull-out grippers back and forth in a moving direction parallel to the trajectory.

One or more sensors may be provided to detect successful loading and/or unloading.

Preferably, the pull-in grippers are moveable along the trajectory, in an X-direction, more preferably at least as far/long as a maximum substrate/strip length. The pull-in grippers are preferably also moveable in a vertical, or, Z-direction to allow the substrate/strip to be moved without collision. The pull-in grippers furthermore may have a load position and a park position.

An embodiment relates to an aforementioned apparatus, wherein, when the loading station comprises input magazines for storing substrates, the pull-in gripper moving devices are configured for moving the pull-in grippers back and forth in a moving direction parallel to the trajectory towards and away from the input magazines.

An embodiment relates to an aforementioned apparatus, wherein the pull-in device comprises:
a stationary frame;
and wherein the pull-in gripper moving devices comprise:
a guide mounted to the frame and extending in the moving direction, wherein the pull-in grippers are mounted to the guide such that they are movable over the carriage during use; and
a drive unit for moving the pull-in grippers along the guide.

In an embodiment, the stationary frame extends over the trajectory adjacent the input magazines and such that the carriage can be moved to underneath the frame;
and wherein the pull-in grippers are suspended from the guide such that they are movable over the carriage when underneath the frame. This is a very robust manner of positioning and moving the pull-in grippers.

Analogous to the pull-in grippers, the pull-out grippers are preferably moveable along the trajectory, in an X-direction, more preferably at least as far/long as a maximum substrate/strip length. The pull-out grippers are preferably also moveable in a Z-direction to allow the substrate/strip to be subsequently moved while on the carriage without collision with the pull-out grippers. The pull-out grippers furthermore may have a load position and a park position.

An embodiment relates to an aforementioned apparatus, wherein, when the unloading stations comprises output magazines for storing therein the substrates, the pull-out gripper moving devices are configured for moving the pull-out grippers through the output magazines in a moving direction parallel to the trajectory. Thus, the substrate can be pulled through the output magazines to be stored therein, without the pull-out gripper moving devices standing in the way, so to speak.

An embodiment relates to an aforementioned apparatus,
wherein the pull-out device comprises, when the loading stations comprises input magazines for storing substrates:
   a stationary frame on a side of the output magazines facing away from the bonding station;
and wherein the pull-out gripper moving devices comprises:
   a guide mounted to the frame and extending in the moving direction,

An embodiment relates to an aforementioned apparatus, further comprising:
a heating device for applying heat to the substrates when supported by the support surface,
preferably wherein the heating device is arranged for applying the heat to the substrates through the support surface.

Such a heater function may provide a constant temperature but may also be programmable to follow a predefined temperature profile. Such a heater function may for instance be needed for a bond process where a die attach film (DAF) on a die needs to reach a certain temperature to melt and provide the adhesion that concludes the bond process.

Further, the heating device could consist of multiple heating zones that allow for individual temperature settings for each zone.

An embodiment relates to an aforementioned apparatus, further comprising:
one or more vertical moving devices that allow vertical movement of the input magazines with respect to the support surface of the carriage, to minimize the risk of damage.

Thus, the substrate can subsequently be pulled smoothly onto the support surface without risk of damaging the substrate. Preferably, the vertically moveable input magazines allow the substrates to be flush with the support surface.

An embodiment relates to an aforementioned apparatus, wherein the pull-in gripper and/or the pull-out gripper are arranged for mechanically gripping said end of the substrates or arranged for gripping said end of the substrates using an underpressure.

An embodiment relates to an aforementioned apparatus, wherein the downholding device comprises a holding member on top of the support surface, which holding member is movable towards and away from the support surface and configured for engaging at least parts of one or more circumferential edges of the substrate in a lower, holding position thereof and positioned at a distance above or on the side (in case of a sideways, rotational movement) of the support surface in a higher, inactive position thereof.

The holding member may for instance comprise mechanical, electro-mechanical, magnetic or hydraulic/pneumatic downholding means.

An embodiment relates to an aforementioned apparatus, wherein the holding member, at opposing transverse edges of the carriage, comprises respective passages configured such that the pull-in devices can pass in a horizontal direction therethrough when pulling the substrates onto the support surface of the carriage, and/or such that the pull-out devices can pass in a horizontal direction therethrough when pulling the substrates off of the support surface of the carriage, at least in the inactive position of the holding member.

In an embodiment, the holding member is frame-shaped and has one or more holding frame parts each positioned and arranged for contacting one or more respective edges of the substrates along at least a part of the length of the edge. In an embodiment, the holding member has multiple holding pins, each holding pin positioned on the holding member such that it engages the substrates at an edge of the substrates in the holding position. The pins could be spring-loaded.

An embodiment relates to an aforementioned apparatus, wherein the carriage moving device comprises a linear guide and a drive for driving the carriage so as to move along the linear guide, the drive preferably comprising a belt drive.

Such a configuration is relatively small, consuming comparatively little space, and is relatively cost-effective.

An embodiment relates to an aforementioned apparatus, wherein the support surface is rectangular and configured to support the entire surface of the substrates.

An embodiment relates to an aforementioned apparatus, wherein the downholding device is arranged for holding the substrates onto the supporting surface using an underpressure.

The downholding device may for instance comprise boreholes or porous material to apply an underpressure or (over) pressurized air to the substrates and air ducts connected to at least one underpressure generator and/or pressurized air source, respectively. Such an underpressure contributes to holding a substrate on the surface in an effective manner. An overpressure may for example be temporarily applied when pulling the substrates on and/or off the carriage so as to further reduce any friction between the substrates and the supporting surface.

An embodiment relates to an aforementioned apparatus, wherein the downholding device comprises channels provided in the carriage, wherein the channels are configured such that an underpressure for holding the substrates onto the support surface can be applied through the channels.

Preferably, the underpressure, in use, is first active in a center region of the support surface and then propagates to edges of the support surface, to achieve even “downholding”, which increases yield.

An embodiment relates to an aforementioned apparatus,
wherein the components are of a type chosen from the list consisting of semiconductor chips, dies, semiconductor packages, integrated circuits, optical elements, electronic elements, electro-optical elements, electro-mechanical, or any combination thereof; and/or
wherein the substrates are strip shaped preferably having a length to width ratio of three to one or two to one.

An embodiment relates to an aforementioned apparatus, the apparatus comprising two or more of said transport devices, and having individual loading stations and individual unloading stations for each of the two or more transport devices.

Such an apparatus allows optimal configuration of “lanes” according to a customer's production needs: the number of lanes is configured based on the number of quality grades (bin codes) to ensure outstanding throughput, improved cost of ownership and minimal floor-space.

An embodiment relates to an aforementioned apparatus, wherein the amount of transport devices corresponds to the number of supplied bin codes, plus one.

Another aspect of the invention relates to a method of bonding one or more components and one or more substrates, using an aforementioned apparatus, comprising:
loading the substrates onto the carriage at the loading stations, by pulling the substrates onto the support surface of the carriage with the pull-in devices;
each time transporting the substrates with the transport device along a trajectory from the loading stations to the bonding station;
bonding the components to the substrates at the bonding station;
each time transporting the substrates with the transport device along a trajectory from the bonding station to the unloading stations after the components have been bonded thereto at the bonding station; and
unloading the substrates from the carriage at the unloading stations, by pulling the substrates off of the support surface of the carriage with the pull-out devices.

An embodiment relates to an aforementioned method, wherein before or after the bonding at the bonding station, respectively, a pre-bond inspection and/or pre-bond cleaning, and/or a post-bond inspection and/or post-bond-cleaning take place.

The modules for pre- and post-bond inspection and/or cleaning are preferably arranged in the moving direction (X) and arranged such that the substrates do not need to leave the support plate and the downholding can remain activated.

Embodiments of apparatuses according to the invention are applicable in an analogous manner to embodiments of methods according to the invention, and vice versa. Likewise, effects of embodiments of apparatuses according to the invention are applicable to corresponding method embodiments as well, and vice versa.

### BRIEF DESCRIPTION OF THE DRAWINGS

The invention will be explained in more detail below, with reference to illustrative embodiments shown in the drawings. Therein:

FIG. 1a shows an example embodiment of an apparatus according to the invention with four transport devices;

FIG. 1b shows an example embodiment of a loading station, such as the loading station shown in FIG. 1a, wherein a substrate is loaded onto a support surface of a carriage from an input magazine by a pull-in device;

FIG. 1c shows an example embodiment of a loading station, such as the loading station shown in FIG. 1b, wherein a substrate has been loaded onto a support surface of a carriage from an input magazine by a pull-in device;

FIG. 2a shows an example embodiment of an apparatus according to the invention, such as the apparatus shown in FIG. 1a, wherein a substrate is moved along the trajectory of the apparatus;

FIG. 2b shows an example embodiment of a loading station, such as the loading station shown in FIG. 2a, wherein a substrate is moved along the trajectory after the substrate has been loaded onto a support surface of a carriage from an input magazine by a pull-in device;

FIGS. 3a and 3b show example embodiments of an unloading station, such as the unloading station shown in FIG. 2a, wherein a substrate is unloaded from a support surface of a carriage into an output magazine by a pull-out device;

FIG. 3c shows an example embodiment of an unloading station, such as the unloading station shown in FIGS. 2a, 3a and 3b, wherein a substrate has been unloaded from a support surface of a carriage into an output magazine by a pull-out device; and

FIG. 4 shows an example embodiment of a carriage moving device with a linear guide and a drive for driving the carriage so as to move the carriage along the linear guide.

### DETAILED DESCRIPTION

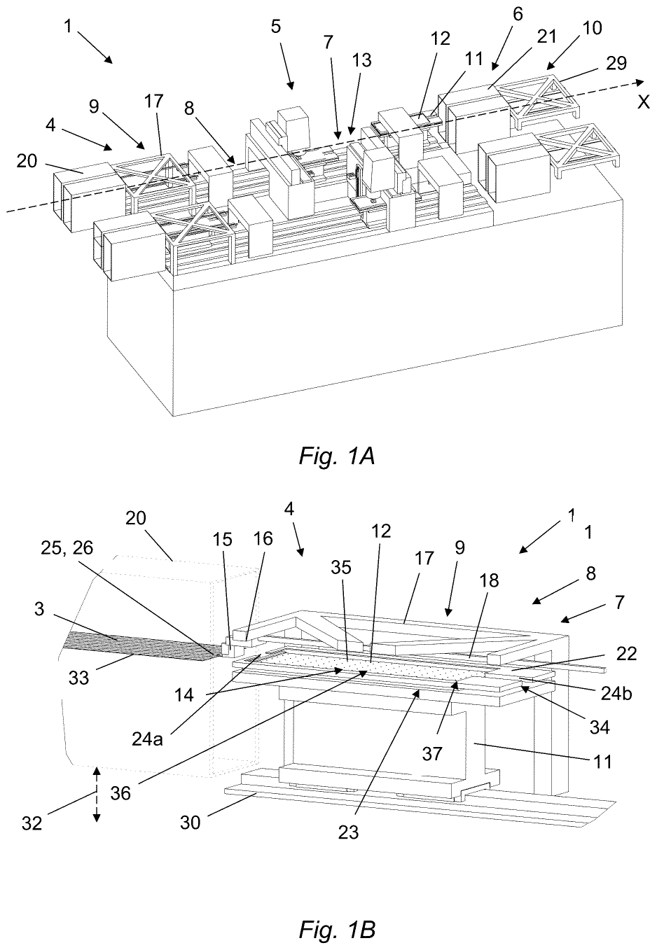

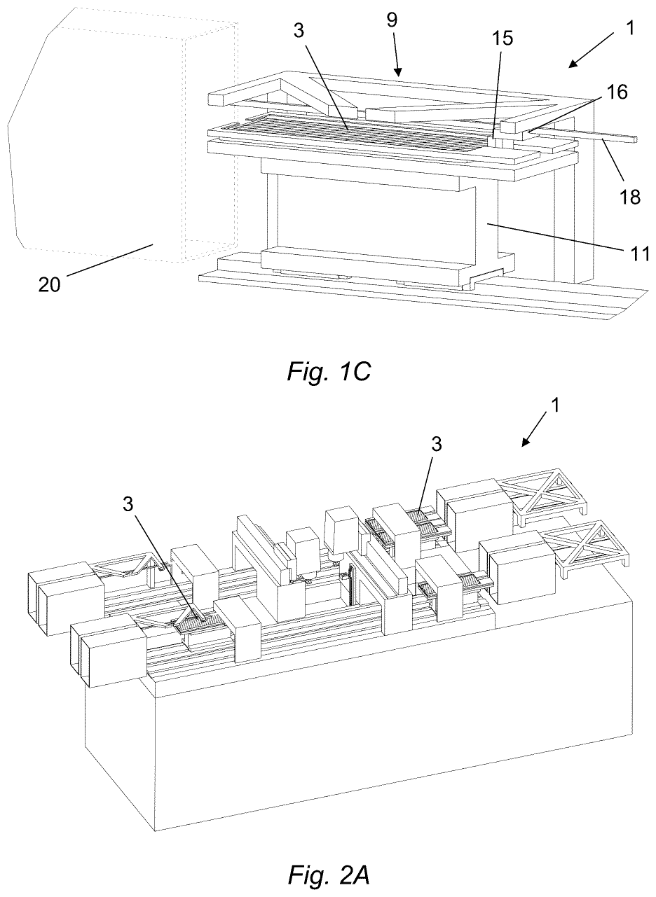

FIGS. 1a-4 will be discussed in conjunction. As mentioned in the foregoing, FIG. 1a shows an example embodiment of an apparatus 1, in particular a die bonder, according to the invention with four transport devices (or “transport lanes”) 7. More specifically, FIG. 1a shows an apparatus 1 for bonding one or more components, such as NAND and DRAM memory dies, to one or more substrates (indicated with reference numeral 3 in the other Figures, such as FIG. 1b). The apparatus 1 comprises a bonding station 5 for bonding the components (such as ultra-thin dies having a thickness of <15 μm) to the substrates, wherein one or more of the components are to be bonded to each of the multiple of substrates at the bonding station 5. The transport device 7 may alternatively or additionally also comprise an inspection station instead of a bonding station 5. The bonding station 5 may comprise two point-to-line pick and place systems which are capable to perform the die sorting process without considerable drop in productivity or alternatively produce without the die sorting process with a relatively high throughput when compared to e.g. NAND die bonding equipment currently available. A post-bond process may optionally also be performed, such as cleaning, inspection or heating. After unloading the substrate 3 at the unloading station 6, the support surface 12 may also be cleaned or inspected. The apparatus 1 may furthermore be provided with advanced inspection features, such as UVI, crack detection, airborne and stationary particle detection, a touch screen, et cetera.

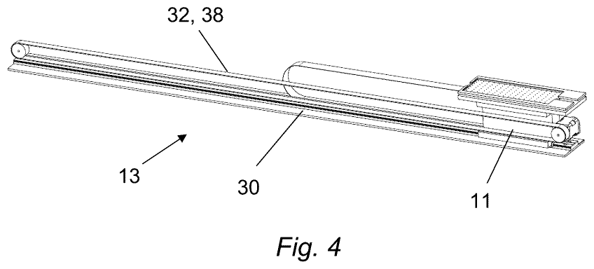

Each transport device 7 is configured for each time transporting one of said multiple substrates along a trajectory 8 from a loading station 4, via the bonding station 5, to an unloading station 6, in a movement direction X. Each transport device 7 comprises a carriage 11 having a flat support surface 12 for supporting the substrate thereon, a carriage moving device 13 for moving the carriage 11 along the trajectory 8 (as more clearly shown in FIG. 4) and a downholding device (indicated with reference numeral 14 in the other Figures, such as FIG. 1b) for holding the substrate on the support surface 12. The transport device 7 furthermore comprises a loading station 4 for loading the substrates onto the carriage 11, comprising a pull-in device 9 for pulling said one of the multiple substrates onto the support surface 12 of the carriage 11 and an unloading station 6 for unloading the substrates after one or more of the components have been bonded thereto at the bonding station 5, comprising a pull-out device 10 for pulling said one of the multiple substrates off of the support surface 12 of the carriage 11. Pulling the often ultra-thin substrates e.g. out of an input magazine and into an output magazine (as shown in the other Figures) is important to ensure a relatively high yield. Common loading and unloading modules are based on pusher rods or roller drives which show a relatively high rate of strip/substrate 3 jamming issues.

The main influencing parameters regarding the amount of transport devices 7 to be used are the number of die quality classifications (bin codes/types) on the wafer and the throughput objective. The support surface 12 preferably is designed with a certain stiffness, such as able to withstand at least 50 N, for instance at least 100 N.

The loading station 4 may comprise an input magazine 20 for storing therein a multiple of said substrates 3, wherein the pull-in device 9 is configured for pulling said one of the multiple substrates from the input magazine 20 directly onto the support surface 12 of the carriage. Analogously, the unloading station 6 may comprise an output magazine 21 for storing therein the multiple substrates after the one or more of the components have been bonded thereto at the bonding station 5, wherein the pull-out device 10 is configured for pulling said one of the multiple substrates off of the support surface 12 of the carriage 11 and directly into the output magazine 21.

Although four transport devices 7 are shown in FIG. 1a, the apparatus 1 may generally comprise two or more of said transport devices 7, such as two to four of such transport devices 7, having an individual said pull-in device 9 and said pull-out device 10 for each of the two or more transport devices 7. However, an option might be to use a pull-in device 9 for more than one input magazine 20, by introducing a Y-axis to the gripping device. The amount of transport devices 7 may correspond to the number of supplied bin codes/qualities/types, or, to the number of supplied bin types, plus one. When three bin types are supplied, the amount of transport devices 7 may for instance be three or four. Preferably, each transport device/lane 7 handles a single bin type. Preferably, one bin type per substrate 3 is used. Analogously, preferably one bin type per loading station 4 and/or unloading station 6 is used (such as one bin type per input magazine 20 and/or output magazine 21). The bonding station 5 may comprise one or more die ejectors, a first (left) picker, a second (right) picker, a first (left) transfer table and a second (right) transfer table, a first (left) bond arm, a second (right) bond arm (all not shown for sake of clarity). When, for instance, three bin codes are supplied, a first transport device/lane 7 may handle the first bin type, a second transport device/lane 7 may handle the second bin type and a third transport device/lane 7 may handle the third bin type. A first substrate 3 associated with the first bin type may be situated relatively “left” on the trajectory 8 of the first transport device 7 (relatively closer to the loading station 4) and a second, respectively third, substrate 3 associated with the second, respectively third, bin type, may have progressed farther along the trajectory 8, being therefore relatively “right” on the trajectory 8 (relatively closer to the unloading station 6). The die ejector may then supply a die with the first bin type to the first picker, first transfer table and first bond arm, subsequently, wherein the first bond arm places the die with the first bin type on the associated substrate 3 of the first transport device 7. The die ejector may then also supply a die with the second, respectively third bin type to the second picker, second transfer table and second bond arm, subsequently, wherein the second bond arm places the die with the second, respectively third, bin type on the associated substrate 3 of the second, respectively third, transport device 7. Thus, an efficient multi-lane bonding process with a relatively high throughput can be achieved.

FIG. 1b shows an example embodiment of a loading station 4, such as the loading station 4 shown in FIG. 1a, wherein a substrate 3 is loaded onto a support surface 12 of a carriage 11 from an input magazine 20 by a pull-in device 9. As shown in FIG. 1b, the pull-in device 9 may comprise a pull-in gripper 15 for gripping a, when viewed in a movement direction (X) along the trajectory 8, front end 25 of the substrate 3, that means, an end 26 facing the carriage 11 and a pull-in gripper moving device 16 for moving the pull-in gripper 15 back and forth in a moving direction parallel to the trajectory 8, in particular towards and away from the input magazine 20. The pull-in gripper 15 may comprise a mechanical gripper and/or a suction tip. The input magazine 20 and/or output magazine 21 may be movable/removable from a respective transport device/lane 7 with e.g. a transfer robot.

The pull-in device 9 may furthermore comprise a stationary frame 17. The pull-in gripper moving device 16 may comprise a guide 18 mounted to the frame 17 and extending in the moving direction (X), wherein the pull-in gripper 15 is mounted to the guide 18 such that it is movable over the carriage 11 during use. A drive unit for moving the pull-in gripper 15 along the guide 18 may also be provided (not shown). The pull-in device 9 may include sensors to detect successful substrate 3 engagement (e.g. mass flow sensors or distance sensors).

The apparatus 1 may further comprise a heating device 23 for applying heat to the substrate 3 when supported by the support surface 12. The heating device 23 is preferably arranged for applying the heat to the substrate 3 through the support surface 12. The heating device 23 may comprise heating wires embedded in the support surface or provided directly thereunder, temperature sensors, et cetera. The heating device 23 may have dimensions of e.g. 300 mm (in the moving direction)×100 mm (in a transverse direction). The support surface 12 preferably also comprises a cooling function.

The apparatus 1 may also comprise a (schematically indicated) vertical moving device 32 for vertically moving the input magazine 20 such that said one of the multiple substrates 3, which is to be pulled out of the input magazine 20 by the pull-in device 9, is moved to a vertical level flush with the support surface 12 of the carriage 11.

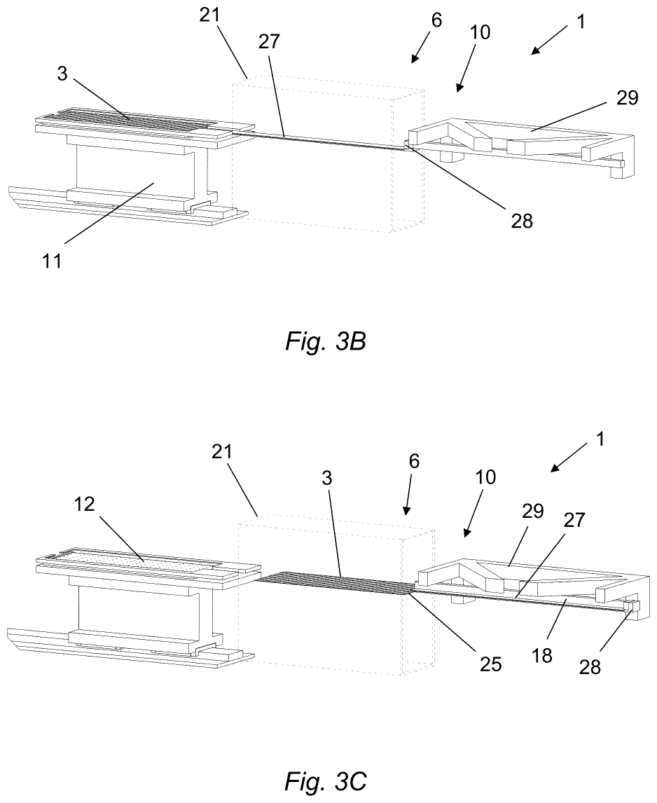

The pull-in gripper 15 (and/or the pull-out gripper 27 as shown in e.g. FIG. 3b) may be arranged for mechanically gripping the end 25 of the substrate 3 or arranged for gripping said end 25 of the substrate 3 using an underpressure, such as a vacuum.

The downholding device 14 may comprise a holding member 22 on top of the support surface 12, which holding member 22 is movable towards and from the support surface 12 and configured for engaging at least parts of one or more circumferential edges 33 of the substrate 3 in a lower, holding position thereof and positioned at a distance above the support surface in a higher, inactive position thereof. The holding member 22, at opposing transverse edges 34 of the carriage 11 may comprise respective passages 24a, 24b configured such that the pull-in device 9 can pass in a horizontal direction therethrough when pulling the substrate 3 onto the support surface 12 of the carriage 11, and/or such that the pull-out device 10 can pass in a horizontal direction therethrough when pulling the substrate 3 off of the support surface 12 of the carriage 11 (as shown in FIGS. 3b and 3c), at least in the inactive position of the holding member 22.

Preferably, the support surface 12 is rectangular and configured to support the entire surface of the substrate 3.

The downholding device 14 may be arranged for holding the substrate 3 onto the supporting surface 12 using an underpressure, such as an underpressure. Therein, the downholding device 14 may comprise channels 35 provided in the carriage 11. The channels 35 are preferably configured such that an underpressure for holding the substrate 3 onto the support surface 12 can be applied through the channels 35, and such that the underpressure, in use, is first active in a center region 36 of the support surface 12 and then propagates to edges 37 of the support surface 12. The support surface 12 may also comprise boreholes or porous material to apply under- or overpressurized air to the substrate 3 from below in addition to the channels 35 connected to at least one pressurized air source. The pressurized air may be needed to cool down the support surface 12 and substrate 3 in case of a production stop and/or to temporarily apply an overpressure when pulling a substrate onto the supporting surface.

The apparatus 1 is preferably arranged for bonding components and substrates 3,
wherein the components are of a type chosen from the list consisting of semiconductor chips, dies, semiconductor packages, integrated circuits, optical elements, electronic elements, electro-optical elements, electro-mechanical, or any combination thereof; and/or wherein the substrates 3 are strip-shaped preferably having a length to width ratio of three to one or two to one.

FIG. 1c shows an example embodiment of a loading station 4, such as the loading station 4 shown in FIG. 1b, wherein a substrate 3 has been loaded onto a support surface 12 of a carriage 11 from an input magazine 20 by a pull-in device 9.

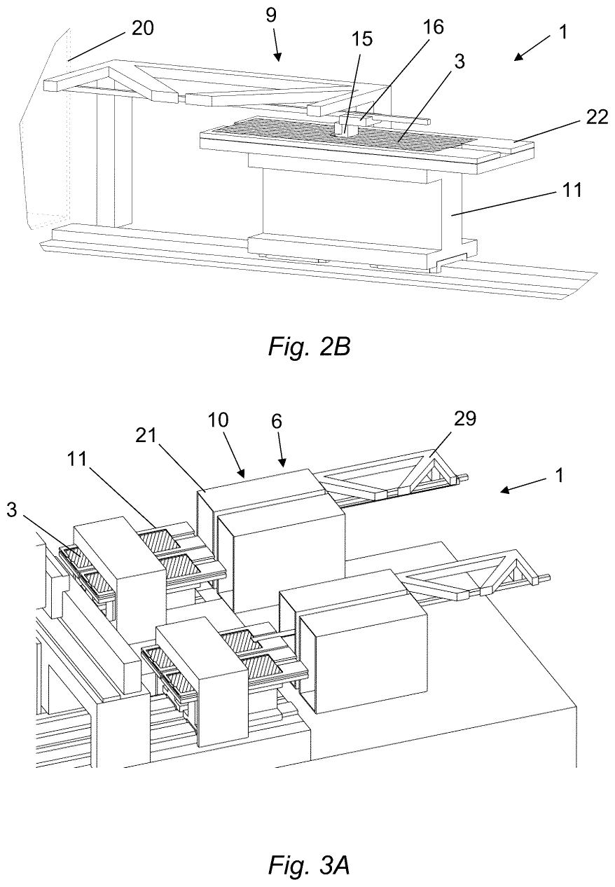

FIG. 2a shows an example embodiment of an apparatus 1 according to the invention, such as the apparatus 1 shown in FIG. 1a, wherein a substrate 3 is moved along the trajectory of the apparatus 1, as shown in the left portion of FIG. 2a. The right portion of FIG. 2a shown three substrates 3 waiting to be unloaded.

FIG. 2b shows an example embodiment of a loading station 4, such as the loading station 4 shown in FIG. 2a, wherein a substrate 3 is moved along the trajectory after the substrate 3 has been loaded onto a support surface 12 of a carriage 11 from an input magazine 20 by a pull-in device 9.

FIGS. 3a and 3b show example embodiments of an unloading station 6, such as the unloading station 6 shown in FIG. 2a, wherein a substrate 3 is unloaded from a support surface 12 of a carriage 11 into an output magazine 21 by a pull-out device 10.

FIG. 3c shows an example embodiment of an unloading station 6, such as the unloading station 6 shown in FIGS. 2a, 3a and 3b, wherein a substrate 3 has been unloaded from a support surface 12 of a carriage 11 into an output magazine 21 by a pull-out device 10. FIG. 3c more clearly shows that the pull-out device 10 may comprise a pull-out gripper 27 for gripping a, when viewed in a movement direction (X) along the trajectory, front end 25 of the substrate 3; and a pull-out gripper moving device 28 for moving the pull-out gripper 27 back and forth in a moving direction parallel to the trajectory. As shown in FIG. 3c, the pull-out gripper moving device 28 is preferably configured for moving the pull-out gripper 27 through the output magazine 21 in a moving direction parallel to the trajectory.

The pull-out device 10 may furthermore comprise a stationary frame 29 on a side of the output magazine 21 facing away from the bonding station 5. The pull-out gripper moving device 28 may comprise a guide 18 mounted to the frame 29 and extending in the moving direction (X). The pull-out gripper moving device 28 may move over the guide 18 in the movement direction (X).

FIG. 4 shows an example embodiment of a carriage moving device 13 with a linear guide 30 and a drive 32 for driving the carriage 11 so as to move the carriage 11 along the linear guide 30. The drive 32 preferably comprises a belt drive 38. The linear guide 30 preferably runs from the loading station 4 all the way to the unloading station 6, without interruptions.

As mentioned before, another aspect of the invention concerns a method of bonding components and substrates 3, using an apparatus 1 as shown in the Figures, comprising: loading the substrates 3 onto the carriage 11 at the loading station 4, by pulling said one of the multiple substrates 3 directly onto the support surface 12 of the carriage with the pull-in device 9; each time transporting one of said multiple substrates 3 with the transport device 7 along a trajectory 8 from the loading station 4 to the bonding station 5; bonding the components to the substrates 3 at the bonding station 5; each time transporting one of said multiple substrates 3 with the transport device 7 along a trajectory 8 from the bonding station to the unloading station 6 after the one or more of the components have been bonded thereto at the bonding station 5; and unloading the substrates 3 from the carriage 11 at the unloading station 6, by pulling said one of the multiple substrates 3 off of the support surface 12 of the carriage 11 with the pull-out device 10.

Although the disclosure has been described above with reference to example embodiments, variants within the scope of the present disclosure will readily occur to those skilled in the art after reading the above description. Such variants are within the scope of the independent claims and the dependent claims. In addition, it is to be understood that express rights are requested for variants as described in the dependent claims. It should also be noted that the example embodiments shown in the Figures, or features thereof, may be combined to yield embodiments not explicitly shown in the Figures.

### LIST OF REFERENCE NUMERALS

1. Apparatus
2. -
3. Substrate
4. Loading station
5. Bonding station
6. Unloading station
7. Transport device
8. Trajectory
9. Pull-in device
10. Pull-out device
11. Carriage
12. Flat support surface
13. Carriage moving device
14. Downholding device
15. Pull-in gripper
16. Pull-in gripper moving device
17. Stationary frame (pull-in)
18. Guide
19. -
20. Input magazine
21. Output magazine
22. Holding member
23. Heating device
24. Passage in holding member (24a, 24b)
25. Front end of substrate
26. Front end of substrate facing carriage
27. Pull-out gripper
28. Pull-out gripper moving device
29. Stationary frame (pull-out)
30. Linear guide
31. Drive
32. Vertical moving device
33. Circumferential edge of substrate
34. Transverse edge of carriage
35. Channel for providing underpressure
36. Center region of support surface
37. Edge of support surface
38. Belt drive
X. Moving direction

1. An apparatus (1) for bonding one or more components and one or more substrates (3), the apparatus comprising:
a bonding station (5) for bonding the components to the substrates, wherein the components are to be bonded to the substrates at the bonding station;
a transport device (7) for each time transporting the substrates along a trajectory (8) from one or more loading stations (4), via the bonding station, to one or more unloading stations (6), the transport device comprising:
a carriage (11) having a flat support surface (12) for supporting the substrates thereon;
a carriage moving device (13) for moving the carriage along the trajectory; and
a downholding device (14) for holding the substrates on the support surface;
one or more loading stations (4) for loading the substrates onto the carriage, comprising one or more pull-in devices (9) for pulling the substrates onto the support surface of the carriage; and
one or more unloading stations (6) for unloading the substrates after the components have been bonded thereto at the bonding station, comprising one or more pull-out devices (10) for pulling the substrates off of the support surface of the carriage.

2. The apparatus (1) according to claim 1,
wherein the loading stations (4) comprise one or more input magazines (20) for storing therein the substrates (3), wherein the pull-in devices (9) are configured for pulling the substrates from the input magazines onto the support surface (12) of the carriage; and/or
wherein the unloading stations (6) comprise one or more output magazines (21) for storing therein the substrates after the components have been bonded thereto at the bonding station (5), wherein the pull-out devices (10) are configured for pulling the substrates off of the support surface of the carriage (11) and into the output magazines.

3. The apparatus (1) according to claim 1,
wherein the pull-in devices (9) comprise:
one or more pull-in grippers (15) for gripping a, when viewed in a movement direction (X) along the trajectory, front end (25) of the substrates (3), such as an end (26) facing the carriage (11); and
one or more pull-in gripper moving devices (16) for moving the pull-in grippers back and forth in a moving direction parallel to the trajectory; and/or
wherein the pull-out devices (10) comprise:
one or more pull-out grippers (27) for gripping a, when viewed in a movement direction along the trajectory, front end (25) of the substrates; and
one or more pull-out gripper moving devices (28) for moving the pull-out grippers back and forth in a moving direction parallel to the trajectory.

4. The apparatus (1) according to claim 3,
wherein the loading stations (4) comprise one or more input magazines (20) for storing therein the substrates (3), wherein the pull-in devices (9) are configured for pulling the substrates from the input magazines onto the support surface (12) of the carriage; and/or
wherein the unloading stations (6) comprise one or more output magazines (21) for storing therein the substrates after the components have been bonded thereto at the bonding station (5), wherein the pull-out devices (10) are configured for pulling the substrates off of the support surface of the carriage (11) and into the output magazines,
wherein the pull-out gripper moving devices (28) are configured for moving the pull-out grippers (27) through the output magazines (21) in a moving direction parallel to the trajectory.

5. The apparatus (1) according to claim 1, further comprising:
a heating device (23) for applying heat to the substrates (3) when supported by the support surface (12).

6. The apparatus (1) according to claim 2, comprising:
one or more vertical moving devices (32) that allow vertical movement of the input magazines (20) with respect to the support surface (12) of the carriage (11).

7. The apparatus (1) according to claim 3, wherein the pull-in grippers (15) and/or the pull-out grippers (27) are arranged for mechanically gripping said end (25) of the substrates or arranged for gripping said end of the substrates using an underpressure.

8. The apparatus (1) according to claim 1, wherein the downholding device (14) comprises a holding member (22) on top of the support surface (12), which holding member is movable towards and away from the support surface and configured for engaging at least parts of one or more circumferential edges (33) of the substrates (3) in a lower, holding position thereof and positioned at a distance above or on a side of the support surface in an inactive position thereof.

9. The apparatus (1) according to claim 8, wherein the holding member (22), at opposing transverse edges (34) of the carriage (11), comprises respective passages (24a,b) configured such that the pull-in devices (9) can pass in a horizontal direction therethrough when pulling the substrates (3) onto the support surface (12) of the carriage, and/or such that the pull-out devices (10) can pass in a horizontal direction therethrough when pulling the substrates off of the support surface of the carriage, at least in the inactive position of the holding member.

10. The apparatus (1) according to claim 1, wherein the carriage moving device (13) comprises a linear guide (30) and a drive (32) for driving the carriage (11) so as to move along the linear guide.

11. The apparatus (1) according to claim 1 in, wherein the downholding device (14) is arranged for holding the substrates (3) onto the supporting surface (12) using an underpressure.

12. The apparatus (1) according to claim 11, wherein the downholding device (14) comprises channels (35) provided in the carriage (11), wherein the channels are configured such that an underpressure for holding the substrates (3) onto the support surface (12) can be applied through the channels.

13. The apparatus (1) according to claim 12, wherein the underpressure, in use, is first active in a center region (36) of the support surface and then propagates to edges (37) of the support surface.

14. The apparatus (1) according to claim 1,
wherein the components are of a type chosen from the list consisting of semiconductor chips, dies, semiconductor packages, integrated circuits, optical elements, electronic elements, electro-optical elements, electro-mechanical, or any combination thereof; and/or
wherein the substrates are strip-shaped.

15. The apparatus (1) according to claim 1, the apparatus comprising two or more of said transport devices (7), and having an individual said loading station (4) and said unloading station (6) for each of the two or more transport devices.

16. The apparatus (1) according to claim 15, wherein the amount of transport devices (7) corresponds to the number of supplied bin codes, plus one.

17. A method of bonding one or more components and one or more substrates (3), using an apparatus (1) according to claim 1, comprising:
loading the substrates onto the carriage (11) at the loading stations (4), by pulling the substrates onto the support surface (12) of the carriage with the pull-in devices (9);
each time transporting the substrates with the transport device (7) along a trajectory (8) from the loading stations (4) to the bonding station (5);
bonding the components to the substrates at the bonding station;
each time transporting the substrates with the transport device (7) along a trajectory (8) from the bonding station to the unloading stations (6) after the components have been bonded thereto at the bonding station; and
unloading the substrates from the carriage at the unloading stations by pulling the substrates off of the support surface of the carriage with the pull-out devices (10).

18. The method according to claim 17, wherein before or after the bonding at the bonding station, respectively, a pre-bond inspection and/or pre-bond cleaning, and/or a post-bond inspection and/or post-bond-cleaning take place.
